(19) United States
(12) Patent Application Publication
(10) Pub. No.: US 2026/0337009 A1
(43) Pub. Date: Oct. 29, 2026

(54) MICROPHONE ASSEMBLY AND ELECTRONIC DEVICE

(71) Applicant: Memsensing Microsystems (Suzhou, China) Co., Ltd., Suzhou, Jiangsu (CN)

(72) Inventors: Yanzi MENG, Suzhou, Jiangsu (CN); Genlan RONG, Suzhou, Jiangsu (CN); Binbin CAO, Suzhou, Jiangsu (CN)

(73) Assignee: Memsensing Microsystems (Suzhou, China) Co., Ltd., Suzhou, Jiangsu (CN)

(21) Appl. No.: 19/117,652

(22) PCT Filed: Oct. 13, 2023
(86) PCT No.: PCT/CN2023/124452

§ 371 Date: Apr. 2, 2025

(30) Foreign Application Priority Data
Oct. 13, 2022 (CN) 202222701591.8

(51) Int. Cl. B81B 3/00; H04R 1/08

(52) U.S. Cl. CPC B81B 3/0072; H04R 1/083; B81B 2201/0257; B81B 2203/0127; B81B 2203/0315; B81B 2203/0323; H04R 2201/003

(57) ABSTRACT

A microphone assembly and an electronic device. The microphone assembly includes at least one diaphragm (101), a back plate (102) disposed opposite the diaphragm (101), and at least one air release column (103) having one end fixedly connected to the back plate (102). In a direction perpendicular to a thickness direction of the diaphragm (101), an edge portion (1032) of the other end of the at least one air release column (103) is spaced apart from the diaphragm (101) by a preset distance, thereby forming at least one air release groove (1011).

### CROSS-REFERENCE TO RELATED APPLICATIONS

This application claims the benefit of China Patent Application No. 202222701591.8 filed with the China National Intellectual Property Administration on Oct. 13, 2022 and entitled “MICROPHONE ASSEMBLY AND ELECTRONIC DEVICE”, the disclosures of which are incorporated by reference herein in their entirety.

### TECHNICAL FIELD

The embodiments of the present application relate to, but are not limited to, a microphone assembly and an electronic device.

### BACKGROUND

During the packaging and use of the microphone chip, sometimes it is subjected to high pressure impacts from the outside, causing the diaphragm to undergo large deformation due to force. Stress concentration occurs along the fixed boundary of the diaphragm, causing the diaphragm to rupture along the fixed boundary and resulting in product failure. Therefore, corresponding air release structures have been set for the diaphragm in the current microphone assemblies.

### Technical Solutions

In the first aspect, the embodiments of the present application provide a microphone assembly, the microphone assembly includes at least one diaphragm, a back plate corresponding to the at least one diaphragm, and at least one air release column with one end fixedly connected to the back plate;
in the direction perpendicular to the thickness of the diaphragm, the edge portion of the other end of the at least one air release column is spaced apart from the diaphragm by a preset distance, so as to form at least one air release groove.

Optionally, the at least one air release column includes a plurality of air release columns and the at least one air release groove includes a plurality of air release grooves;
the plurality of air release grooves divide the diaphragm into a deformed zone and a non-deformed zone, the non-deformed zone is fixedly connected to the back plate;
when deformation occurs in the deformed zone, the width of each of the plurality of air release grooves increases in the direction perpendicular to the thickness of the diaphragm, thereby increasing an air release volume.

Optionally, the deformed zone is a middle region of the diaphragm;
the air release grooves are evenly spaced around the circumferential direction of the diaphragm.

Optionally, the at least one air release column includes a body portion and an edge portion;
one end of the main body portion is fixedly connected to the back plate and the other end of the main body portion is fixedly connected to the edge portion.

Optionally, the main body portion includes a bottom portion fixedly connected to the back plate and a side portion disposed around the bottom portion and connected to the bottom portion, the bottom portion and the side portion form a cavity.

Optionally, the main body portion includes a top portion fixedly connected to the edge portion and a side portion disposed around the top portion and connected to the top portion;
the side portion is fixedly connected to the back plate, and the side portion, the top portion and the back plate form a cavity;
the at least one air release column further includes at least one support column disposed within the cavity and fixedly connected to the back plate, the main body portion is coated on the outer surface of the support column.

Optionally, the back plate is provided with at least one sound hole corresponding to the at least one air release groove;
on a plane perpendicular to the thickness direction of the diaphragm, the projection of the air release groove partially overlaps with the projection of the corresponding sound hole.

Optionally, the air release groove is a polygonal annular structure, on a plane perpendicular to the thickness direction of the diaphragm, the projection of a part of the edge area of the polygonal annular structure overlaps with the projection of the back plate, and the projection of the other part of the edge area of the polygonal annular structure overlaps with the projection of the sound hole.

Optionally, an anti-stick structure is provided on the surface of the diaphragm close to the back plate.

Optionally, an anti-sticking structure is provided on the surface of the back plate close to the diaphragm.

Optionally, the microphone assembly further includes: a substrate, the substrate has a cavity penetrating the substrate in the thickness direction thereof, the sound hole on the back plate is communicated with the cavity, the back plate is fixedly connected to one side surface of the substrate through at least one first support member;
the back plate includes a first insulating layer connected to the first support member, a conductive layer located on a surface of the first insulating layer away from the substrate, and a second insulating layer covering the first insulating layer and the conductive layer, the second insulating layer is fixedly connected to the diaphragm through at least one second support member;
the at least one air release column is fixedly connected to the back plate through the second insulating layer.

Optionally, the microphone assembly further includes: a substrate, the substrate has a cavity penetrates the substrate in the thickness direction, the diaphragm is fixedly connected to one side surface of the substrate through at least one first support member, and the at least one air release groove is communicated with the cavity;
the back plate includes a first insulating layer fixedly connected to the diaphragm through at least one second support member and a conductive layer located on the surface of the first insulating layer away from the diaphragm;
the at least one air release column is fixedly connected to the back plate through the first insulating layer.

Second aspect, the embodiments of the present application also provide an electronic device, the electronic device includes the microphone assembly of any embodiment provided by the present application.

### BRIEF DESCRIPTION OF THE DRAWINGS

To describe technical solutions in embodiments of this present application more clearly, the following briefly introduces the accompanying drawings for describing the embodiments. It is apparent that the accompanying drawings in the following descriptions show merely some embodiments of this application, and a person skilled in the art may still derive other drawings from these accompanying drawings without creative efforts.

FIG. 1 is a structural schematic diagram of the microphone assembly, according to embodiment 1 of the present application;

FIG. 2 is a top view of the microphone assembly, according to embodiment 1 of the present application;

FIG. 3 is a structural schematic diagram of the microphone assembly, according to embodiment 2 of the present application;

FIG. 4 is a structural schematic diagram of the microphone assembly, according to embodiment 3 of the present application;

FIG. 5 is a structural schematic diagram of the microphone assembly, according to embodiment 4 of the present application.

### DETAILED DESCRIPTION

The following will refer to the accompanying drawings in the embodiments of the present application to clearly and completely describe the technical solutions in the embodiments of the present application. Obviously, the described embodiments are only a part of the embodiments of the present application, not all of the embodiments. Based on the embodiments in the present application, all other embodiments obtained by those skilled in the art without creative efforts belong to the scope of protection of the present application.

The air release structures include two types. One is to design through-holes on the diaphragm. When the diaphragm withstands a large impact force, the air pushed by the pressure will enter the rear cavity of the package from the air release holes, resulting in an increase in the air volume in the rear cavity. The air release volume of this structure cannot be adjusted. When the pressure continuously acts on the diaphragm, due to the increase in the air volume in the rear cavity, it becomes more difficult for the diaphragm to compress the rear cavity when deformed, which is equivalent to an increase in the stiffness of the diaphragm and a reduction in the stress concentration caused by the deformation of the diaphragm. The hole-shaped air release structure will cause a large change in the low-frequency sensitivity of the microphone and affect the signal-to-noise ratio of the product. The other type is to create air release slits on the diaphragm, and there is an air release structure on the diaphragm corresponding to the position of the air release slits that can swing up and down. When the diaphragm operates under normal sound pressure, the air release structure is closed, and the change in low-frequency sensitivity is small. When the chip is subjected to a large impact force, the air release structure vibrates and thus adjusts the air release volume. However, this air release structure may cause the diaphragm to tear when the sound pressure is large, thereby causing the entire product to fail.

The present application discloses a microphone assembly and an electronic device. The microphone assembly includes a diaphragm, a back plate correspondingly arranged with the diaphragm, and at least one air release column with one end fixedly connected to the back plate. At least one air release groove corresponding to the at least one air release column is provided on the diaphragm. The other end of the air release column extends into the corresponding air release groove. The air release groove and the corresponding air release column form an air release structure. On the one hand, the back plate is fixedly connected to the air release column. Thus, the strength of the air release column is higher than that of the diaphragm, and the connection strength with the back plate is higher. When the gas pressure introduced 101 into the microphone assembly is large, the damage of the air release column will not result in the cracking of the diaphragm, thereby improving the reliability of the microphone assembly. On the other hand, only corresponding air release grooves need to be provided on the diaphragm. In the thickness direction of the diaphragm and the direction perpendicular to the thickness of the diaphragm, the vibration of the diaphragm changes the distance between the air release groove and the air release column. Thus, as the gas pressure introduced into the microphone assembly changes, the distance between the air release groove and the air release column changes, thereby changing the air release volume. Moreover, there is no need to set an air release structure that can vibrate up and down on the diaphragm, which helps to avoid the tearing of the diaphragm when the gas pressure introduced into the microphone assembly.

The pressure sensing structure and electronic device in the present application will be described in details in combination with the accompanying drawings and specific embodiments.

### Embodiment 1

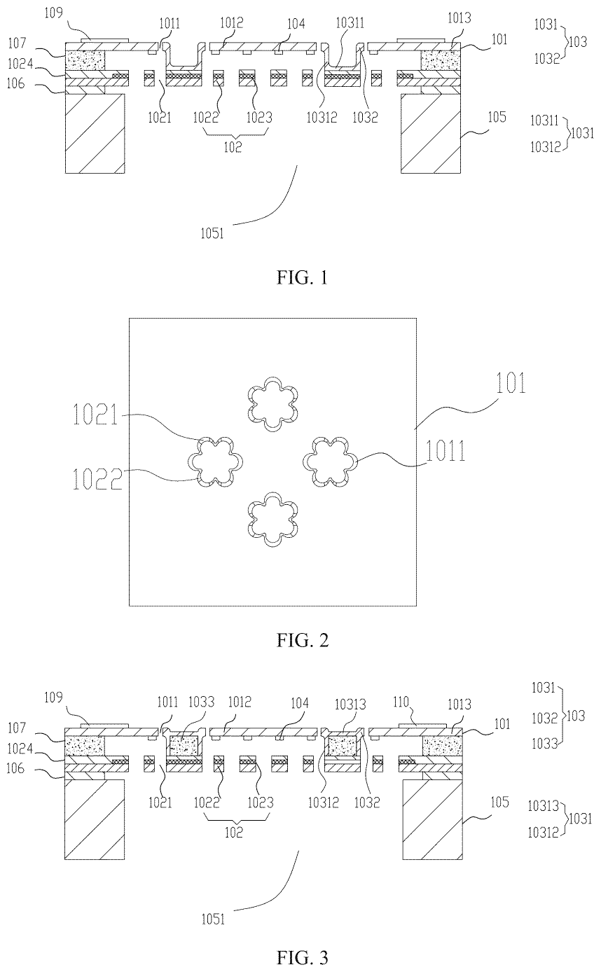

As shown in FIG. 1, the embodiments of the present application provide a microphone assembly, the microphone assembly includes a diaphragm 101, a back plate 102 corresponding to the diaphragm 101, and at least one air release column 103 with one end fixedly connected to the back plate 102;

In the direction perpendicular to the thickness direction of the diaphragm 101, the edge portion 1032 of the other end of at least one air release column 103 is spaced apart from the diaphragm 101 by a preset distance, so as to from at least one air release groove 1011.

In this embodiment, the air release groove 1011 and the corresponding air release column 103 form an air release structure. When the gas pressure is too high and the diaphragm 101 deforms, the gas flows from the gap between the air release groove 1011 and the corresponding air release column 103 to the rear cavity, increasing the air volume of the rear cavity to balance the pressures of the front and rear cavities and improve the mechanical reliability of the product.

In this embodiment, on the one hand, the back plate 102 is fixedly connected to the air release column 103. Thus, the strength of the air release column 103 is higher than that of the diaphragm 101, and the connection strength with the back plate 102 is higher. When the gas pressure introduced into the microphone assembly is large, the damage of the air release column 103 will not result in the cracking of the diaphragm 101, thereby improving the reliability of the microphone assembly. On the other hand, only the corresponding air release groove 1011 needs to be disposed on the diaphragm 101. In the direction perpendicular to the thickness of the diaphragm 101, the vibration of the diaphragm 101 changes the width of the air release groove 1011, thereby changing the air release volume. Moreover, there is no need to set an air release structure that can vibrate up and down on the diaphragm 101, which avoids the tearing of the diaphragm 101 when the gas pressure is introduced into the microphone assembly.

Further, there are a plurality of air release columns 103 and a plurality of air release grooves 1011.

A plurality of air release grooves 1011 divide the diaphragm 101 into a deformed zone 1012 and a non-deformed zone 1013, the non-deformed zone 1013 is fixedly connected to the back plate 102.

When deformation occurs in the deformed zone 1012, the width of each air release groove 1011 increases in the direction perpendicular to the thickness of the diaphragm 101, thereby increasing the air release volume.

In this embodiment, as shown in FIG. 1, there are a plurality of air release columns 103 and a plurality of corresponding air release grooves 1011. A plurality of air release grooves 1011 divide the diaphragm 101 into a deformed zone 1012 and a non-deformed zone 1013. Further, the area surrounded by a plurality of air release grooves 1011 is the deformed zone 1012. Thus, after the gas is introduced into the microphone assembly, the diaphragm 101 deforms in the direction facing the back plate 102, and only the deformed zone 1012 deforms. When the deformed zone 1012 deforms, in the thickness direction of the diaphragm 101 and the direction perpendicular to the thickness of the diaphragm 101, the width of each air release groove 1011 increases, thereby increasing the air release volume, so that the air release volumes of a plurality of release grooves 1011 can all change with the gas pressure introduced into the microphone assembly.

Further, the deformed zone 1012 is a middle region of the diaphragm 101.

The air release grooves 1011 are evenly spaced around the circumferential direction of the diaphragm 101.

In this embodiment, the middle area of the diaphragm 101 is usually the area with a large deformation amount. Therefore, the deformed zone 1012 is set as the middle area of the diaphragm 101, thereby improving the sensitivity of the microphone assembly. Moreover, the air release grooves 1011 are evenly arranged in the circumferential direction of the diaphragm 101, making the air release positions of the diaphragm 101 more uniform and avoiding the cracking of the diaphragm 101 caused by a large impact force on a certain area of the diaphragm 101 when the gas pressure introduced into the microphone assembly is large.

Further, the at least one air release column 103 includes a body portion 1031 and an edge portion 1032.

One end of the main body portion 1031 is fixedly connected to the back plate 102, and the other end is fixedly connected to the edge portion 1032. The edge portion 1032 is located in the corresponding air release groove 1011 and is spaced a preset distance from the diaphragm 101.

In this embodiment, each air release column 103 includes the main body portion 1031 and the edge portion 1032. Further, the edge portion 1032 is located in the corresponding air release groove 1011, the main body portion 1031 is located between the diaphragm 101 and the back plate 102, the edge portion 1032 is located in the corresponding air release groove 1011 and is spaced a preset distance from the diaphragm 101, and when the gas is introduced into the microphone assembly, in the thickness direction of the diaphragm 101 and the direction perpendicular to the thickness of the diaphragm 101, the distance between the edge portion 1032 and the corresponding air release groove 1011 increases, thereby changing the intake gas volume entering the rear cavity.

Further, the main body portion 1031 includes a bottom portion 10311 fixedly connected to the back plate 102 and a side portion 10312 disposed around the bottom portion 10311 and connected to the bottom portion 10311, the bottom portion 10311 and the side portion 10312 form a cavity.

In this embodiment, the main body portion 1031 includes the bottom portion 10311 fixedly connected to the back plate 102 and the side portion (10312) arranged around the bottom portion 10311 and connected to the bottom portion 10311. The bottom portion 10311 and the side portion 10312 form a cavity, reducing the weight of the air release column 103 and thereby reducing the pressure on the back plate 102. The other side of the cavity is a non-closed structure. Thus, when the gas pressure introduced into the microphone assembly is large, the cavity can share a part of the gas pressure to avoid causing large impact force on the diaphragm 101 and avoid resulting in damage to the diaphragm 101.

Further, the bottom portion 10311 and the side portion 10312 are formed using the same material and manufacturing process as the diaphragm 101.

Further, the back plate 102 is provided with at least one sound hole 1021 corresponding to the at least one air release groove 1011.

On a plane perpendicular to the thickness direction of the diaphragm 101, the projection of the air release groove 1011 partially overlaps with the projection of the corresponding sound hole 1021.

Further, the air release groove 1011 is a polygonal annular structure, on a plane perpendicular to the thickness direction of the diaphragm 101, the projection of a part of the edge area of the polygonal annular structure overlaps with the projection of the back plate 102, and the projection of the other part of the edge area of the polygonal annular structure overlaps with the projection of the sound hole 1021.

In this embodiment, as shown in FIG. 1, when the diaphragm 101 deforms under a large sound pressure, as for the edge of the air release groove 1011 corresponding to the deformation area 1012 of the diaphragm 101, a part of the edge is in contact with the sound hole 1021 and another part of the edge is in contact with the back plate 102. Compared to a circular and regular boundary, when the gas pressure is so large that the deformation area 1012 of the diaphragm 101 undergoes a large deformation, the boundary of the air release groove 1011 of the diaphragm 101 does not completely cover the sound hole 1021, and the sound pressures of the front and rear cavities can still be balanced through the sound hole 1021 to reduce the failure rate of the product.

For example, as shown in FIG. 2, each side of the air release groove 1011 is arc-shaped, and the shape of the air release groove 1011 is formed by six arcs. This embodiment does not limit the specific shape of the air release groove 1011.

Further, an anti-sticking structure 104 is provided on the surface of the diaphragm 101 close to the back plate 102, and/or, an anti-sticking structure 104 is provided on the surface of the back plate 102 close to the diaphragm 101.

In this embodiment, in order to avoid product failure caused by the contact between the diaphragm 101 and the back plate 102, an anti-sticking structure 104 is provided. The anti-sticking structure 104 can be either provided on the surface of the diaphragm 101 close to the back plate 102, or on the surface of the back plate 102 close to the diaphragm 101, or on both the surface of the diaphragm 101 close to the back plate 102 and the surface of the back plate 102 close to the diaphragm 101.

The form of the anti-sticking structure 104 can be various. For example, it can be a dot-like structure or a conical structure, this embodiment does not limit this.

Further, the microphone assembly further includes a substrate 105, the substrate 105 having a cavity 1051 that penetrates the substrate 105 in the thickness direction, the sound hole 1021 on the back plate 102 is communicated with the cavity, the back plate 102 is fixedly connected to one side surface of the substrate 105 through a first support member 106.

The back plate 102 includes a first insulating layer 1022 fixedly connected to the first support member 106 and a conductive layer 1023 located on the surface of the first insulating layer 1022 away from the substrate 105.

The conductive layer 1023 and a second insulating layer 1024 covering the first insulating layer 1022 and the conductive layer 1023 are provided on the back plate 102. The second insulating layer 1024 is fixedly connected to the diaphragm 101 through a support member 107.

Among them, at least one air release column 103 is fixedly connected to the back plate 102 through the second insulating layer 1024.

In this embodiment, a front port structure is provided. That is, after the gas is introduced into the microphone assembly, it directly acts on the diaphragm 101, and then passes through the gap between the air release groove 1011 and the air release column 103 and enters the cavity 1051 through the sound hole 1021 on the back plate 102.

### Embodiment 2

Different from Embodiment 1, as shown in FIG. 3, the main body portion 1031 includes a top portion 10313 fixedly connected to the edge portion 1032 and a side portion 10312 arranged around the top portion 10313 and connected to the top portion 10313; the side portion 10312 is fixedly connected to the back plate 102, and the side portion 10312, the top portion 10313 and the back plate 102 form a cavity; At least one air release column 103 further includes a support column 1033 located in the cavity and fixedly connected to the back plate 102. The main body portion 1031 is coated on the outer surface of the support column 1033, and the main body portion 1031 is supported by the support column 1033, thereby improving the strength of the air release column 103 and reducing the failure probability of the air release column 103.

Further, the top portion 10313 and the side portion 10312 are formed using the same material and manufacturing process as the diaphragm 101, and the support column 1033 and the second support member 107 are formed using the same material and manufacturing process.

For other technical details of this embodiment, please refer to the description of Embodiment 1, and all the beneficial effects of Embodiment 1 can be achieved, which will not be repeated here.

### Embodiment 3

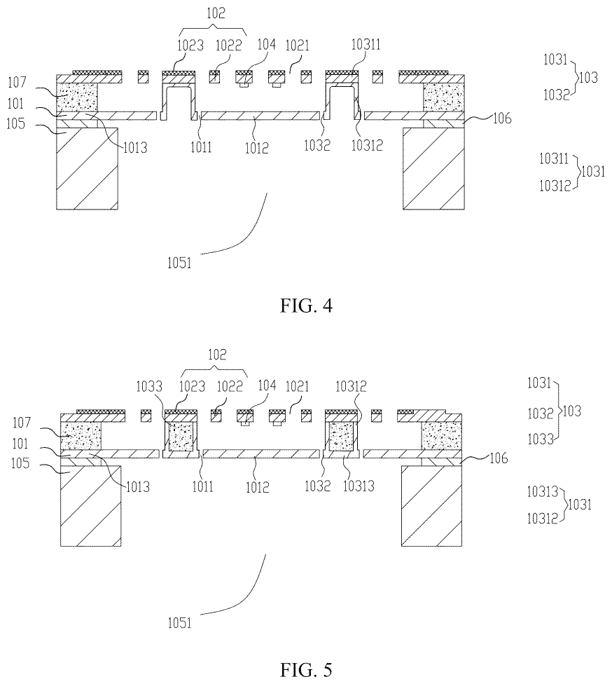

Different from Embodiment 1, as shown in FIG. 4, in this embodiment, the microphone assembly includes a substrate 105. The substrate 105 has a cavity 1051 penetrating the substrate 105 in the thickness direction. The diaphragm 101 is fixedly connected to one surface of the substrate 105 through the first support member 106, and at least one air release groove 1011 is in communication with the cavity 1051.

The back plate 102 includes a first insulating layer 1022 fixedly connected to the diaphragm 101 through a second support member 107 and a conductive layer 1023 located on the surface of the first insulating layer 1022 away from the diaphragm 101.

Among them, at least one air release column 103 is fixedly connected to the back plate 102 through the first insulating layer 1022.

In this embodiment, a back port structure is provided, that is, after the gas is introduced into the microphone assembly and enters the cavity 1051, it directly acts on the diaphragm 101, and then passes through the gap between the air release groove 1011 and the air release column 103 and further passes through the sound hole 1021 on the back plate 102.

For other technical details of this embodiment, please refer to the description of Embodiment 1, and all the beneficial effects of Embodiment 1 can be achieved, which will not be repeated here.

### Embodiment 4

Different from Embodiment 3, as shown in FIG. 5, the main body portion 1031 includes a top portion 10313 fixedly connected to the edge portion 1032 and a side portion 10312 arranged around the top portion 10313 and connected to the top portion 10313. The side portion 10312 is fixedly connected to the back plate 102, and the side portion 10312, the top portion 10313 and the back plate 102 form a cavity. At least one air release column 103 further includes a support column 1033 located in the cavity and fixedly connected to the back plate 102. The main body portion 1031 is coated on the outer surface of the support column 1033, and the main body portion 1031 is supported by the support column 1033, thereby improving the strength of the air release column 103 and reducing the failure probability of the air release column 103. Further, the top portion 10313 and the side portion 10312 are formed using the same material and manufacturing process as the diaphragm 101, and the support column 1033 and the second support member 107 are formed using the same material and manufacturing process.

For other technical details of this embodiment, please refer to the descriptions of Embodiment 1 and Embodiment 3, and all the beneficial effects of Embodiment 1 can be achieved, which will not be repeated here.

### Embodiment 5

This embodiment provides an electronic device, comprising the microphone assembly of any one of Embodiment 1 to Embodiment 4.

The pressure sensing structure and the electronic device provided in the embodiments of the present application have been introduced in detail above. Specific examples have been applied in this article to explain the principle and implementation method of the present application. The descriptions of the above embodiments are only used to help understand the method and core idea of the present application. At the same time, for those of ordinary skill in the art, according to the idea of the present application, there will be changes in the specific implementation methods and application scope. In conclusion, the content of this specification should not be construed as a limitation of the present application.

The above is only a preferred embodiment of the present invention and is not used to limit the scope of the implementation of the present invention. All equal changes and modifications made according to the shape, structure, characteristics and spirit within the scope of the claims of the present invention shall be included within the scope of the claims of the present invention.

1. A microphone assembly, wherein the microphone assembly comprises: at least one diaphragm, a back plate corresponding to the at least one diaphragm, and at least one air release column with one end fixedly connected to the back plate;
in the direction perpendicular to the thickness of the diaphragm, the edge portion of the other end of the at least one air release column is spaced apart from the diaphragm by a preset distance, so as to form at least one air release groove.

2. The microphone assembly according to claim 1, wherein the at least one air release column comprises a plurality of air release columns and the at least one air release groove comprises a plurality of air release grooves;
the plurality of air release grooves divide the diaphragm into a deformed zone and a non-deformed zone, the non-deformed zone is fixedly connected to the back plate;
when deformation occurs in the deformed zone, the width of each of the plurality of air release grooves increases in the direction perpendicular to the thickness of the diaphragm, thereby increasing an air release volume.

3. The microphone assembly according to claim 2, the deformed zone is a middle region of the diaphragm;
the air release grooves are evenly spaced around the circumferential direction of the diaphragm.

4. The microphone assembly according to claim 1, wherein the at least one air release column comprises a body portion and an edge portion;
one end of the main body portion is fixedly connected to the back plate and the other end of the main body portion is fixedly connected to the edge portion.

5. The microphone assembly according to claim 4, wherein the main body portion comprises a bottom portion fixedly connected to the back plate and a side portion disposed around the bottom portion and connected to the bottom portion, the bottom portion and the side portion form a cavity.

6. The microphone assembly according to claim 4, wherein the main body portion comprises a top portion fixedly connected to the edge portion and a side portion disposed around the top portion and connected to the top portion;
the side portion is fixedly connected to the back plate, and the side portion, the top portion and the back plate form a cavity;
the at least one air release column further comprises at least one support column disposed within the cavity and fixedly connected to the back plate, the main body portion is coated on the outer surface of the support column.

7. The microphone assembly according to claim 1, wherein the back plate is provided with at least one sound hole corresponding to the at least one air release groove;
on a plane perpendicular to the thickness direction of the diaphragm, the projection of the air release groove partially overlaps with the projection of the corresponding sound hole.

8. The microphone assembly according to claim 7, wherein the air release groove is a polygonal annular structure, on a plane perpendicular to the thickness direction of the diaphragm, the projection of a part of the edge area of the polygonal annular structure overlaps with the projection of the back plate, and the projection of the other part of the edge area of the polygonal annular structure overlaps with the projection of the sound hole.

9. The microphone assembly according to claim 1, wherein an anti-stick structure is provided on the surface of the diaphragm close to the back plate.

10. The microphone assembly according to claim 1, wherein an anti-sticking structure is provided on the surface of the back plate close to the diaphragm.

11. The microphone assembly according to claim 1, wherein the microphone assembly further comprises: a substrate, the substrate has a cavity penetrating the substrate in the thickness direction thereof, the sound hole on the back plate is communicated with the cavity, the back plate is fixedly connected to one side surface of the substrate through at least one first support member;
the back plate comprises a first insulating layer connected to the first support member, a conductive layer located on a surface of the first insulating layer away from the substrate, and a second insulating layer covering the first insulating layer and the conductive layer, the second insulating layer is fixedly connected to the diaphragm through at least one second support member;
wherein the at least one air release column is fixedly connected to the back plate through the second insulating layer.

12. The microphone assembly according to claim 1, wherein the microphone assembly further comprises: a substrate, the substrate has a cavity penetrating the substrate in the thickness direction thereof, the diaphragm is fixedly connected to one side surface of the substrate through at least one first support member, and the at least one air release groove is communicated with the cavity;
the back plate comprises a first insulating layer fixedly connected to the diaphragm through at least one second support member and a conductive layer located on the surface of the first insulating layer away from the diaphragm;
wherein the at least one air release column is fixedly connected to the back plate through the first insulating layer.

13. An electronic device, wherein the electronic device comprises a microphone assembly according to claim 1.

14. The microphone assembly according to claim 1, wherein a strength of the air release column is higher than a strength of the diaphragm.

15. The microphone assembly according to claim 5, wherein one side of the cavity is a non-closed structure.

16. The microphone assembly according to claim 1, wherein in the thickness direction of the diaphragm as well as in the direction perpendicular to the thickness of the diaphragm, the vibration of the diaphragm changes the distance between the at least one air release groove and the at least one air release column.

17. The microphone assembly according to claim 1, wherein when the diaphragm deforms under a large sound pressure, as for the edge of the air release groove corresponding to the deformation area of the diaphragm, a part of the edge is in contact with the sound hole and another part of the edge is in contact with the back plate.
